(19) United States
(12) Patent Application Publication
(10) Pub. No.: US 2012/0234243 A1
(43) Pub. Date: Sep. 20, 2012

(54) METHOD AND APPARATUS UTILIZING A SINGLE LIFT MECHANISM FOR PROCESSING AND TRANSFER OF SUBSTRATES

(75) Inventors: Donald J. K. Olgado, Palo Alto, CA (US); Tuan Anh (Mike) Nguyen, San Jose, CA (US)

(73) Assignee: APPLIED MATERIALS, INC., Santa Clara, CA (US)

(21) Appl. No.: 13/413,744

(22) Filed: Mar. 7, 2012

Related U.S. Application Data
(60) Provisional application No. 61/453,462, filed on Mar. 16, 2011.

(51) Int. Cl. C23C 16/458; H01L 21/00

(52) U.S. Cl. 118/730; 118/729; 414/806

(57) ABSTRACT

Embodiments of the present invention relate to apparatus and methods for loading substrates into processing chambers, processing the substrates in the processing chamber, and transferring the substrates out of the processing chamber using a single lift and rotational mechanism. One embodiment of the present invention provides a method for processing one or more substrates. The method includes transferring a substrate carrier, having one or more substrates disposed thereon, to a chamber volume, supporting the substrate carrier within the chamber volume using a set of lift pins, transferring the substrate carrier from the set of lift pins to an edge ring within the chamber volume, and contacting the edge ring with the set of lift pins to control the position of the substrate carrier within the chamber volume.

### CROSS-REFERENCE TO RELATED APPLICATIONS

This application claims benefit of U.S. Provisional Patent Application Ser. No. 61/453,462 (Attorney Docket No. 016208USAL), filed Mar. 16, 2011, which is hereby incorporated by reference herein.

### BACKGROUND OF THE INVENTION

1. Field of the Invention

Embodiments of the present invention relate to apparatus and method for handling substrates during the transfer and processing thereof. More particularly, embodiments of the present invention relate to apparatus and methods for loading substrates into processing chambers, processing the substrates in the processing chamber, and transferring the substrates out of the processing chamber using a single lift and rotation mechanism.

2. Description of the Related Art

In semiconductor processing, a plurality of substrates are often loaded onto substrate carriers, upon which, the substrates are transferred into and out of processing chambers. The substrate carriers may also be utilized to support the substrates during processing. For example, substrates, such as sapphire substrates used in manufacturing of light emitting diodes (LEDs), are usually processed in batches. The batch of substrates is disposed in a substrate carrier that is transferred into the chamber, which is utilized to support the substrates during processing in the chamber, and is employed to transfer the substrates out of the chamber after processing. The carrier transfer sequence is typically performed using a robot blade that extends into and out of the chamber, which requires the substrate carrier to be spaced away from other chamber components during carrier loading and unloading, to allow the robot blade to contact and support the substrate carrier.

However, using substrate carriers for transfer and processing of substrates requires numerous support and rotational apparatus for manipulating the carrier. In one conventional chamber example, one support device is typically used for rotation and elevating of the substrate carrier, while a separate support device is utilized for elevating the substrate carrier during transfer. In another conventional chamber example, the substrate carrier is divided into segments that are a positioned sequentially above a dedicated lift device that facilitates transfer of each section separately.

In both of these examples, multiple moving parts in the chamber increases the risk of collision or damage of parts of the chamber. Damage of parts causes particle contamination and downtime of the chamber which increases cost of ownership of the chamber.

Therefore, there is a need for a method and apparatus for single lift and rotational mechanism that is capable of positioning substrates or substrate carriers during processing and transfer.

### SUMMARY OF THE INVENTION

Embodiments of the present invention relate to apparatus and methods for loading substrates into processing chambers, processing the substrates in the processing chamber, and transferring the substrates out of the processing chamber, using a single lift and rotate mechanism. The lift and rotate mechanism performs dual functions including 1) lifting and lowering a substrate carrier plate within the processing chamber to enable transfer of one or more substrates into and out of the processing chamber, and 2) rotating the substrate carrier plate in the processing chamber during a processing operation of the substrate. Embodiments of the present invention may be used for handling of substrates in processing chambers wherein multiple substrates are processed simultaneously, for example, processing chambers for manufacturing devices such as light emitting diodes (LEDs), laser diodes (LDs), and power electronics.

One embodiment of the present invention provides a method for processing one or more substrates. The method includes transferring a substrate carrier, having one or more substrates disposed thereon, to a chamber volume, supporting the substrate carrier within the chamber volume using a set of lift pins, transferring the substrate carrier from the set of lift pins onto an edge ring within the chamber volume, and contacting the edge ring with the set of lift pins to control the position of the substrate carrier within the chamber volume.

Another embodiment of the present invention provides a method for processing one or more substrates. The method includes transferring one or more substrates, disposed on a substrate carrier supported by a robot blade, to a chamber, moving a plurality of lift pins into contact with the substrate carrier, supporting the substrate carrier above a plane of the robot blade, moving the robot blade out of the chamber, and moving the substrate carrier into a supported position on an edge ring. The method also includes moving the lift pins to a position where each of the plurality of lift pins are engaged with the edge ring, and lifting the edge ring and the substrate carrier to a processing position.

Another embodiment of the present invention provides an apparatus for processing multiple substrates. The apparatus includes a chamber body having an internal sidewall, a liner assembly disposed on the internal sidewall defining a processing volume, and a plurality of chamber support features coupled to an interior surface of the liner assembly and extending into the processing volume. The apparatus also includes an edge ring disposed in the processing volume, the edge ring comprising an annular body, a shoulder portion thereof defining an inner diameter of the annular body, and a plurality of tabs disposed on the shoulder portion in a circular pattern having a diameter that is less than the inner diameter of the annular body. The apparatus also includes a support assembly disposed in the processing volume, the support assembly having at least three lift pins that are movable to a first position to engage the plurality of tabs and a second position to extend through the inner diameter of the annular body.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a schematic side cross-sectional view of a processing chamber according to embodiments described herein.

FIG. 2A is an enlarged view of a portion of the processing chamber of FIG. 1.

FIG. 2B is a top plan view of the processing chamber of FIG. 1.

FIG. 3A is a side cross-sectional view of a portion of one embodiment of a processing chamber along line 3A of FIG. 3B.

FIG. 3B is a top plan view of the processing chamber of FIG. 3A along line 3B.

FIG. 4A is a side cross-sectional view of a portion of a processing chamber along line 4A of FIG. 4B.

FIG. 4B is a top plan view of the processing chamber of FIG. 4A along line 4B.

FIG. 5A is a side cross-sectional view of a portion of a processing chamber along line 5A of FIG. 5B.

FIG. 5B is a top plan view of the processing chamber of FIG. 5A along line 5B.

FIG. 6A is a side cross-sectional view of a portion of a processing chamber along line 6A of FIG. 6B.

FIG. 6B is a top plan view of the processing chamber of FIG. 6A along line 6B.

FIG. 7A is a side cross-sectional view of a portion of a processing chamber along line 7A of FIG. 7B.

FIG. 7B is a top plan view of the processing chamber of FIG. 7A along line 7B,

FIG. 8A is a side cross-sectional view of a portion of a processing chamber along line 8A of FIG. 8B.

FIG. 8B is a top plan view of the processing chamber of FIG. 8A along line 8B.

FIG. 9 is a side cross-sectional view of a portion of processing chamber showing a substrate carrier supported by a plurality of lift pins.

FIG. 10 is a side cross-sectional view of a portion of a processing chamber showing the lift pins adjacent in proximity to tabs extending from an edge ring.

FIG. 11 is a side cross-sectional view a portion of a processing chamber showing the support assembly in a processing position.

To facilitate understanding, identical reference numerals have been used, where possible, to designate identical elements that are common to the figures. It is contemplated that elements disclosed in one embodiment may be beneficially utilized on other embodiments without specific recitation.

### DETAILED DESCRIPTION

Embodiments of the present invention provide apparatus and methods for a single automation device within a processing chamber, such as a single lift and rotational mechanism that facilitates loading, processing, and unloading of one or more substrates into and out of a processing chamber. The lift and rotational mechanism may be utilized in processing of single substrates or multiple substrates in batch processing. In general, processing chambers that may benefit from one or more of the embodiments described herein include thermal processing chambers that are able to perform high temperature thermal processes, such as chemical vapor deposition (CVD), hydride vapor phase epitaxy (HVPE) deposition or other thermal processes used to form or process light emitting diode (LED) and laser diode (LD) devices.

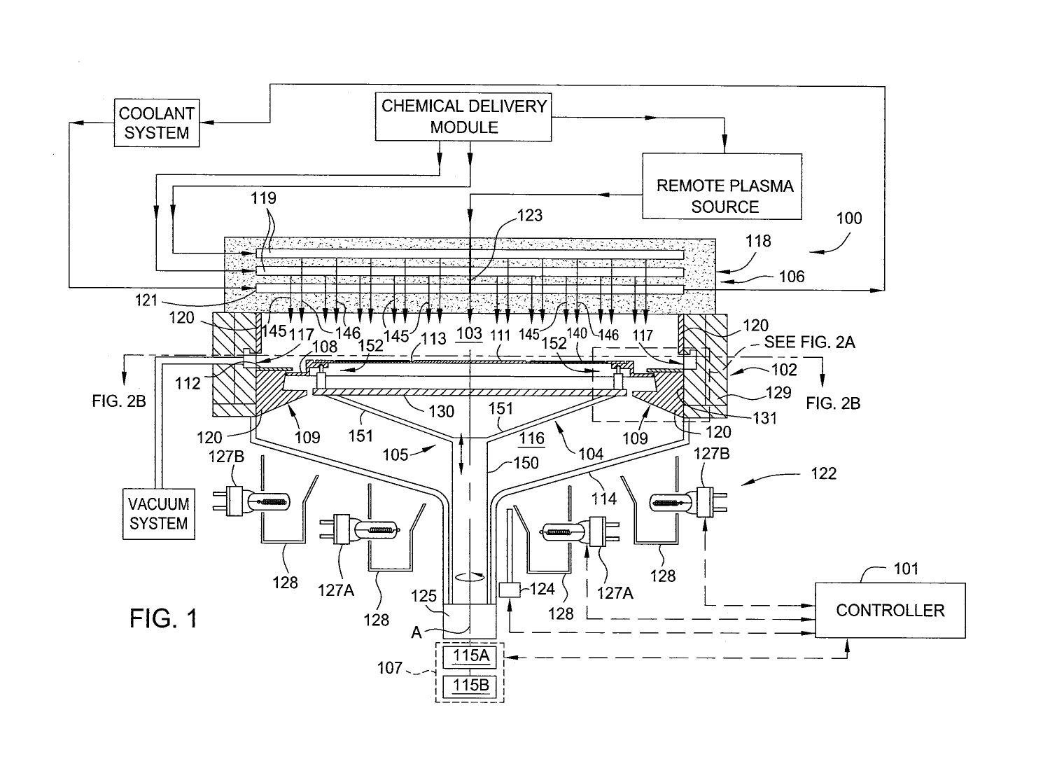

An example of a thermal processing chamber that may benefit from one or more the embodiments described herein is a metal oxide chemical vapor deposition (MOCVD) deposition chamber, which is illustrated in FIG. 1 and is further described below. While the discussion below primarily describes one or more of the embodiments of the present invention being disposed in a MOCVD chamber, this processing chamber type is not intended to be limiting as to the scope of the invention described herein. For example, the processing chamber may be an HVPE deposition chamber that is available from Applied Materials, Inc., of Santa Clara, Calif.

FIG. 1 is a schematic side cross-sectional view of a processing chamber 100 according to one or more embodiments described herein. In one example, as illustrated in FIG. 1, the processing chamber 100 is a metal oxide chemical vapor deposition (MOCVD) chamber. The processing chamber 100 comprises a chamber body 102, a chemical delivery module for delivering process gases thereto, a support assembly 104, an energy source 122, a controller 101 and a vacuum system. The chamber body 102 encloses a processing volume 103 disposed between a lid assembly 106 and a dome structure 114 that is coupled to the chamber body 102. The chamber body 102 comprises a sidewall 129. The sidewall 129 may be a quartz material, a ceramic material or a metallic material. The sidewall 129 may include metallic materials, such as stainless steel or aluminum. A plurality of chamber support structures 109 are disposed on an interior sidewall 131 of the chamber body 102. A liner assembly 120 may be coupled to the interior sidewall 131. In one embodiment, the plurality of chamber support structures 109 are formed on the liner assembly 120. The liner assembly 120 may be a ceramic or include a ceramic coating. The sidewall 129 may also include a coolant channel (not shown) to maintain the sidewall 129 at a temperature lower than the temperature of the processing volume 103.

During processing a substrate carrier 111 is disposed on the support assembly 104. The substrate carrier 111 is generally adapted to support and retain one or more substrates 140 thereon during processing. The substrate carrier 111 is also utilized to transfer the one or more substrates 140 into and out of the processing chamber 100. The substrate carrier 111 is shown in a processing position in FIG. 1, but the substrate carrier 111 may be moved by the support assembly 104 to a lower position where, for example, the substrates 140 and/or substrate carrier 111 may be transferred into or out of the chamber body 102 by commands sent from the controller 101.

The controller 101 is generally designed to facilitate the control and automation of the overall processing chamber 100 and typically may include a central processing unit (CPU) (not shown), memory (not shown), and support circuits (or I/O) (not shown). The CPU may be one of any form of computer processors that are used in industrial settings for controlling various chamber processes and hardware (e.g., motors, fluid delivery hardware, etc.) and monitor the system and chamber processes (e.g., substrate position, support assembly 104 position, process time, etc.). The memory is connected to the CPU, and may be one or more of a readily available memory, such as random access memory (RAM), read only memory (ROM), floppy disk, hard disk, or any other form of digital storage, local or remote. Software instructions and data can be coded and stored within the memory for instructing the CPU. The support circuits are also connected to the CPU for supporting the processor in a conventional manner. The support circuits may include cache, power supplies, clock circuits, input/output circuitry, subsystems, and the like. A program (or computer instructions) readable by the controller 101 determines which tasks are performable on a substrate. Preferably, the program is software readable by the controller 101, which includes code to generate and store at least substrate positional information, support assembly positional information, process chamber recipe information, the sequence of movement of the various controlled components, and any combination thereof.

A single lift and rotational mechanism 105 is disposed at least partially in the processing volume 103. The single lift and rotational mechanism 105 has the capability to lift and lower (i.e., vertically), and rotate within the processing volume The single lift and rotational mechanism 105 comprises a plurality of support features 152 coupled to a common drive device that is configured to provide rotational and vertical movement of the support features 152. In one embodiment, the single lift and rotational mechanism 105 comprises the support assembly 104, having the plurality of support features 152 coupled thereto, and a single support shaft 150 supporting the support assembly 104.

The support assembly 104 is generally configured to support and retain the substrate carrier 111, supported on an edge ring 108, during processing. However, during transfer, the support assembly 104 is configured to support the substrate carrier 111 to facilitate transfer of the substrate carrier 111. During transfer, the edge ring 108 may be temporarily supported by the plurality of chamber support structures 109. The support assembly 104 includes the single support shaft 150 that has a plurality of support arms 151 on which support features 152 are disposed. The support assembly 104 generally includes an actuator assembly 107 that is configured to provide vertical movement and rotation of the support shaft 150 about a central axis A.

During processing, the support assembly 104 supports and rotates the edge ring 108 and the substrate carrier 111 about the central axis A. The actuator assembly 107 may comprise a rotation actuator 115B and a lift actuator 115B that are each adapted cause the support assembly 104 to move or be desirably positioned relative to one or more of the processing chamber 100 components, such as the lid assembly 106. In one configuration, the rotation actuator 115A is a DC servo motor, or stepper motor, that is adapted to position the support features 152 in at least two or more desired angular orientations about the central axis A, by use of commands sent from the controller 101. The rotation actuator 115A is also generally adapted to rotate the support shaft 150, the support features 152 and other desirable components (e.g., edge ring 108, substrate carrier 111) at a desirable rotational velocity and/or acceleration about the central A. In one configuration, the rotation actuator 115A, which is generally positioned outside of the processing volume 103, is coupled to the support shaft 150 through a sealing assembly 125 that is configured to prevent gases inside the processing volume 103 (e.g., process gases) from leaking out, or gases outside the processing volume 103 (e.g., atmospheric gases) from leaking in, by use of one or more conventional elastomeric radial lip seals, or other similar conventional vacuum compatible sealing devices.

In one configuration of the actuator assembly 107, the lift actuator 115B comprises a linear motor, a magnetic drive, or a conventional lead screw, a precision slide assembly and motor (e.g., DC servo motor, stepper motor), that is adapted to position the support features 152 in a desired vertical position (e.g., direction parallel to the central axis A) by use of commands sent from the controller 101. In one configuration, the lift actuator 115B is coupled to the support shaft 150 through the sealing assembly 125, to allow movement of the support shaft 150 relative to various stationary chamber components, and prevent gases inside the processing volume 103 from leaking out, or gases outside the processing volume 103 from leaking in, by use of the one or more conventional elastomeric radial lip seals, or other similar conventional vacuum compatible sealing devices.

In one embodiment of the processing chamber 100, the lid assembly 106 comprises a showerhead assembly 118. The showerhead assembly 118 may include multiple gas delivery channels that are each configured to uniformly deliver one or more processing gases to the substrates disposed in the processing volume 103. In one configuration, the showerhead assembly 118 includes multiple manifolds 119 coupled with the chemical delivery module for delivering multiple precursor gases discretely to the processing volume 103. The showerhead assembly 118 may be made of metallic materials, such as stainless steel or aluminum. A ceramic liner or a ceramic coating may be disposed over the metallic material. The showerhead assembly 118 also includes a temperature control channel 121 coupled with a cooling system to help regulate the temperature of the showerhead assembly 118.

The manifolds 119 are in fluid communication with gas conduits 145 and gas conduits 146 that deliver gases to the processing volume 103 separately from each of the manifolds 119. In some configurations, a remote plasma source is adapted to deliver gas ions or gas radicals to the processing volume 103 via a conduit 123 formed in the showerhead assembly 118. It should be noted that the precursors may comprise a process gas, process gas mixtures, or may comprise one or more precursor gases or process gases as well as carrier gases and dopant gases which may be mixed with the precursor gases.

The dome structure 114 contains a chamber volume 116 and the energy source 122 disposed adjacent to the dome structure 114. An exhaust ring 112 may be disposed around the inside diameter of the chamber body 102. The exhaust ring 112 minimizes deposition from occurring in the chamber volume 116 below the support assembly 104. The exhaust ring 112 also directs exhaust gases from the processing volume 103 to exhaust ports 117. The exhaust ring 112 may be formed from a quartz material. The dome structure 114 may be made of transparent material, such as high-purity quartz, to allow energy (e.g., light) delivered from the energy source 122 to pass through for radiant heating of the substrates 140. The radiant heating provided from the energy source 122 may be provided by a plurality of inner lamps 127A and outer lamps 127B disposed below the dome structure 114. The inner lamps 127A and the outer lamps 127B may be positioned in a circular pattern or rings below the dome structure 114. Reflectors 128 may be used to help control the radiant energy provided by the inner lamps 127A and the outer lamps 127B. Additional rings of lamps may also be used for finer temperature control of the substrates 140. The temperature of the substrates 140 is maintained at a desired processing temperature using a closed-loop control system. The closed-loop control system generally comprises a controller 101. The closed-loop control system may also include a temperature probe 124 such as a pyrometer. In one embodiment, the temperature probe 124 monitors the temperature of the substrates 140. The controller 101 may use the temperature information from the temperature probe 124 to vary power to the energy source 122, vary the spacing of the substrate carrier 111 relative to the energy source 122 and/or the showerhead assembly 118, and combinations thereof.

During processing, the substrate carrier 111 is generally designed to damp the spatial variation in the amount of energy delivered from the energy source 122 to the substrates 140. An optional baffle plate 130 may be disposed on the support assembly 104. The baffle plate 130 is utilized to dampen thermal variation created by any non-uniform distribution of radiant energy from lamps 127A-127B. The substrate carrier 111 is also designed to provide a steady support surface for each substrate 140 during processing and transfer thereon. In one configuration, each of the substrates 140 may be disposed in a recess 113 formed in the substrate carrier 111. The substrate carrier 111 generally comprises a material that is able to withstand the high processing temperatures (e.g., greater than 800° C.) used to process substrates in the processing volume 103 of the processing chamber 100. The substrate carrier 111 generally comprises a material that has good thermal properties, such as a good thermal conductivity. The substrate carrier 111 may also have physical properties similar to the substrates 140, such as a similar coefficient of thermal expansion, to avoid unnecessary relative motion between the surface of the substrate carrier 111 and the substrates 140 during heating and/or cooling. In one example, the substrate carrier 111 may comprise silicon carbide (SiC), or a graphite core that has a silicon carbide coating formed by a CVD process over the core. The edge ring 108 may be formed from a solid silicon carbide material, or a silicon carbide coated graphite material.

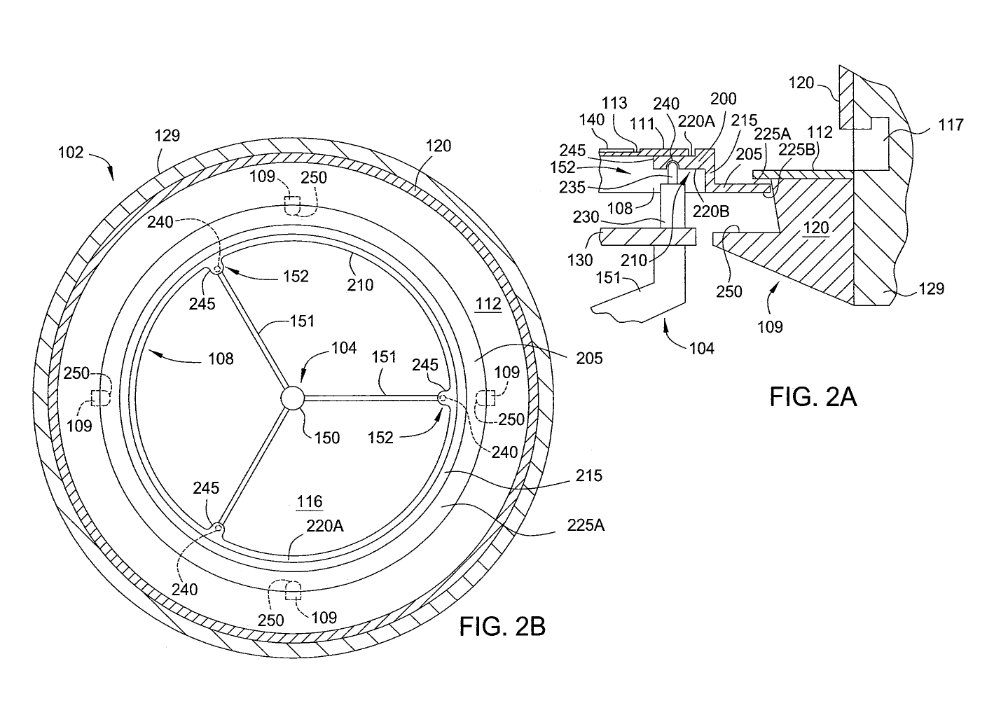

FIG. 2A is an enlarged view of a portion of the processing chamber 100 of FIG. 1. FIG. 2B is a top plan view of the processing chamber 100 of FIG. 1. In FIG. 2A, a portion of the substrate carrier 111 is shown but the substrate carrier 111 is not shown in FIG. 2B for clarity. The edge ring 108 comprises a body 200 that is a generally annular member. The body 200 includes a peripheral flange portion 205 and an inwardly extending shoulder portion 210 opposite the peripheral flange portion 205. The shoulder portion 210 is coupled to the flange portion 205 by an annular wall 215. The shoulder portion 210 includes a first upper surface 220A and a first lower surface 220B. The first upper surface 220A is adapted to receive the periphery of the substrate carrier 111. The body 200 also includes a second upper surface 225A and a second lower surface 225B.

When the substrate carrier 111 is in a processing position as shown, the support assembly 104 supports the edge ring 108 while the first upper surface 220A of the edge ring 108 supports the substrate carrier 111. In one embodiment of a support feature 152 as described in FIG. 1, each of the support arms 151 comprise a support member 230 at the distal end of the support arms 151. In one embodiment, the support member 230 is vertically oriented and substantially parallel to the central axis A (shown in FIG. 1). In this embodiment, the support member 230 includes a lift pin 235 that is received by a notch 240 formed in the shoulder portion 210 of the edge ring 108. In one embodiment, the notch 240 is configured as an indexing feature that facilitates alignment of the edge ring 108 with the lift pin 235. In one aspect, the shoulder portion 210 comprises a discrete, inwardly extending tab 245 formed on the shoulder portion 210. The inwardly extending tab 245 may be an extended feature of the shoulder portion 210. When the support assembly 104 is lowered, such as during transfer of the substrate carrier 111, the second lower surface 225B is adapted to contact an edge ring support surface 250 disposed on the chamber support structures 109. The lift pin 235 is disengaged from the notch 240 and the support assembly 104 may be free to rotate without contacting the edge ring 108 or substrate carrier 111.

The lift pin 235 may be formed from a material that is similar to the material of the edge ring 108 to minimize differences in thermal expansion and minimize thermal losses between the edge ring 108 and the lift pin 235. In one example, the edge ring 108 comprises a silicon carbide material and the lift pins 235 comprise a silicon carbide material. Utilizing lift pins 235 made of the same material as the material of the edge ring 108 minimizes heat loss on portions of the edge ring 108 where the lift pins 235 contact the edge ring 108. The support arms 151 are formed from an insulating material, such as quartz, to reduce thermal conduction to other portions of the support assembly 104. Thus, the lift pins 235 may be heated to substantially the same temperature as the edge ring 108 resulting in minimization of “cold spots” on the substrate carrier 111 during processing. However, the support arms 151 minimize thermal conduction between the lift pins 235 and other portions of the support assembly 104. This results in enabling higher processing temperatures while providing temperature uniformity of the edge ring 108 and the substrates 140 during processing. The support arms 151 prevent thermal conduction to other portions of the chamber body 102.

Additionally, the edge ring 108 shields the exhaust ring 112 from direct radiant energy provided by the energy source 122 during processing. Shielding of the exhaust ring 112 prevents breakage of the exhaust ring 112. For example, the exhaust ring 112 extends into a high temperature region on one end and is coupled to the chamber body 102 on the other end which is relatively cooler. Thus, the exhaust ring 112 is subject to a high thermal gradient which may cause cracking or breakage. The shielding of the exhaust ring 112 by the edge ring 108 during processing minimizes direct heat from the energy source 122 and lowers the thermal gradient of the exhaust ring 112. Additionally, shielding of the exhaust ring 112 enables the edge ring 108 to attain more uniform heat distribution. This minimizes thermal losses at the edge of the substrate carrier 111 during processing.

FIG. 2B is a top plan view of the processing chamber 100 of FIG. 1. The substrate carrier 111 is not shown in FIG. 2B for clarity but would be received in, and supported by, the first upper surface 220A of the shoulder portion 210 of the edge ring 108 during processing. In one embodiment, the shoulder portion 210 of the edge ring 108 comprises a plurality of inwardly extending tabs 245. In one embodiment, the edge ring 108 comprises an inwardly extending tab 245 for each support arm 151. In one aspect, each of the inwardly extending tabs 245 are spaced apart at substantially equal angles, such as about 120 degrees.

In one embodiment, the chamber body 102 comprises a plurality of chamber support structures 109. In this embodiment, four chamber support structures 109 are shown, but more or less may be utilized. Each of the chamber support structures 109 comprise slight protrusions that extend into the chamber volume 116. Each of the chamber support structures 109 are dimensioned to minimize blockage of radiant energy from the inner lamps 127A and outer lamps 127B during processing. The support surface 250 of the chamber support structures 109 comprise a length and width that supports the second lower surface 225B of the edge ring 108 stably when the edge ring 108 is positioned thereon. In one embodiment, only three chamber support structures 109 are utilized. In one aspect, the chamber support structures 109 are spaced apart at substantially equal angles, such as about 120 degrees or about 90 degrees. In other embodiments, the chamber support structures 109 may comprise a continuous ledge disposed on the sidewall 129 of the chamber body 102.

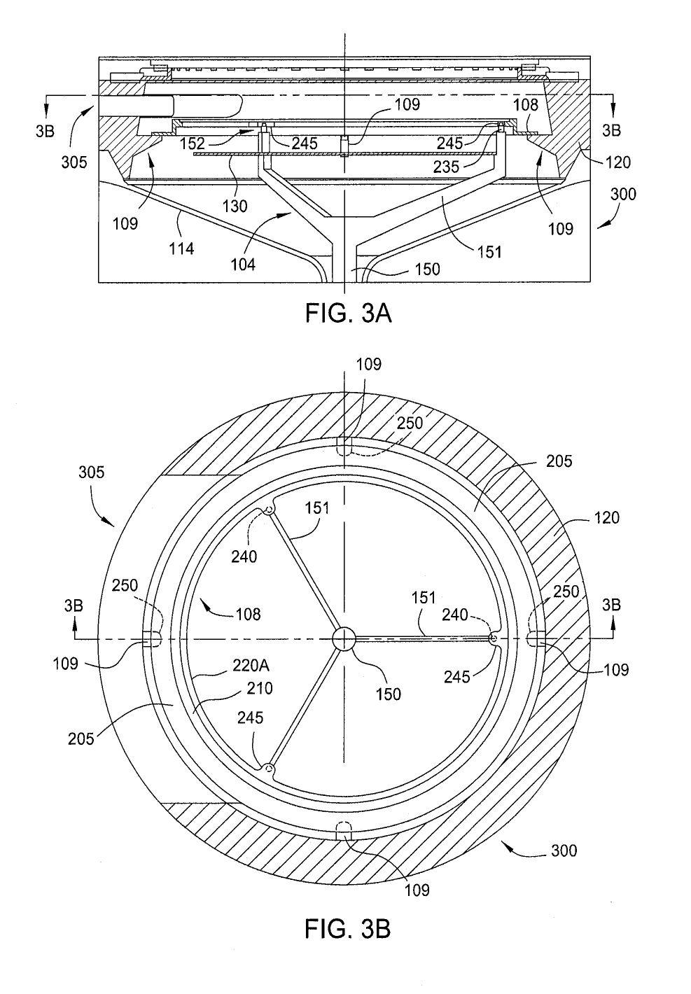

FIGS. 3A-8B are side cross-sectional views and top plan views of a portion of processing chamber 300 illustrating a transfer sequence of an incoming substrate carrier 111 using the support assembly 104 according to embodiments described herein. The support assembly 104 shown in the processing chamber 300 of FIGS. 3A-8B may be utilized in the processing chamber 100 of FIG. 1.

FIG. 3A is a side cross-sectional view of a portion of the processing chamber 300 along line 3A of FIG. 3B. FIG. 3B is a top plan view of the processing chamber 300 along line 3B of FIG. 3A. The processing chamber 300 includes a port 305 formed in a sidewall 310 of the chamber body 102. The port 305 is sized to receive a substrate carrier 111, which is not shown in FIGS. 3A and 3B.

In FIGS. 3A and 3B, the support assembly 104 is in a first or “home” position. The home position of the support assembly 104 may be a vertical or rotational position where the support arms 151 are aligned with the inwardly extending tabs 245 of the edge ring 108. In this position, the support assembly 104 may either move upward to support the edge ring 108 or move downward to place the edge ring 108 on the chamber support structures 109. The home position of the support assembly 104 may also be a rotational position where the support arms 151 are positioned to not interfere with the substrate carrier 111 and a robot blade during transfer through the port 305.

In FIG. 3B, the notches 240 in the inwardly extending tabs 245 of the edge ring 108 are shown in phantom. The notches 240 are shown in a circular pattern similar to a bolt pattern where the notches 240 or the position of each notch 240 are imaginary bolts. The circular pattern comprises a diameter that is less than an inside diameter of the edge ring 108. Although the pattern of notches 240 shown in FIG. 3B may be defined as triangular, the term circular is used based on a radial distance from a geometric center of the support shaft 150 to the center of each notch 240 to illustrate the bolt pattern instead of measuring point to point. Thus, circular is intended to cover a triangular configuration as shown in FIG. 3B, a square configuration in the case where an edge ring 108 having four notches 240 (not shown) is used. Circular may also be used in the case where an edge ring 108 having more than four notches 240 (not shown) is used.

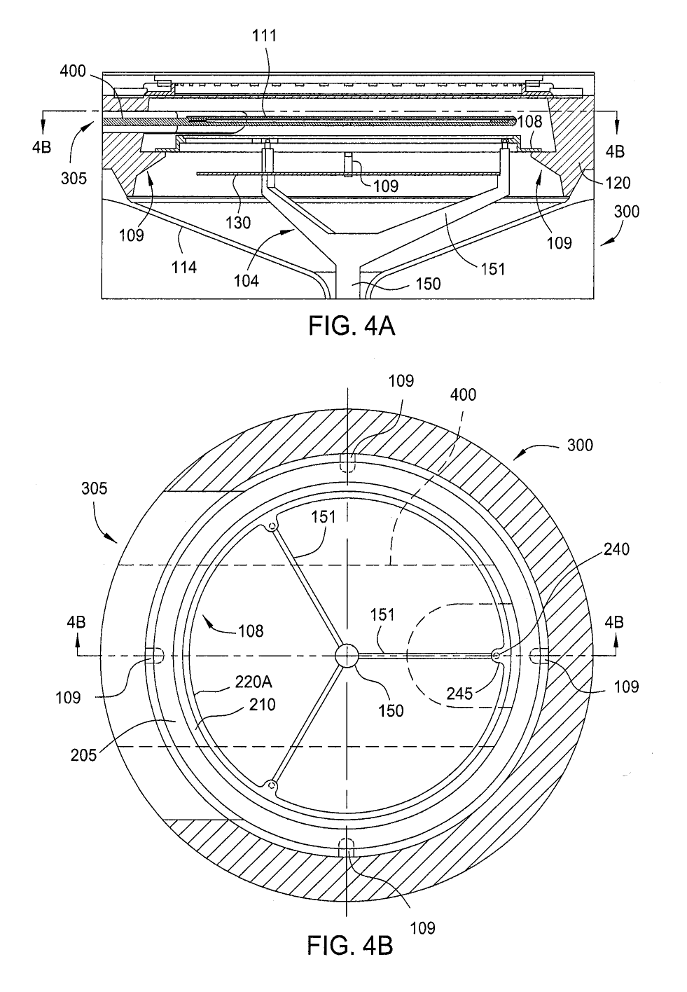

FIG. 4A is a side cross-sectional view of a portion of the processing chamber 300 along line 4A of FIG. 4B. FIG. 4B is a top plan view of the processing chamber 300 along line 4B of FIG. 4A. In FIG. 4A, a robot blade 400 is extended into the processing chamber 300 through the port 305. The robot blade 400 supports the substrate carrier 111 having one or more substrates 140 thereon (not shown in this Figure). The substrate carrier 111 is not shown in FIG. 4B in order to more clearly show the position of the support arms 151. The robot blade 400 is also shown in phantom to show the position of the support arms 151. The first upper surface 220A of the edge ring 108 generally includes an inside diameter that is substantially the same as or slightly greater than an outside diameter of the substrate carrier 111.

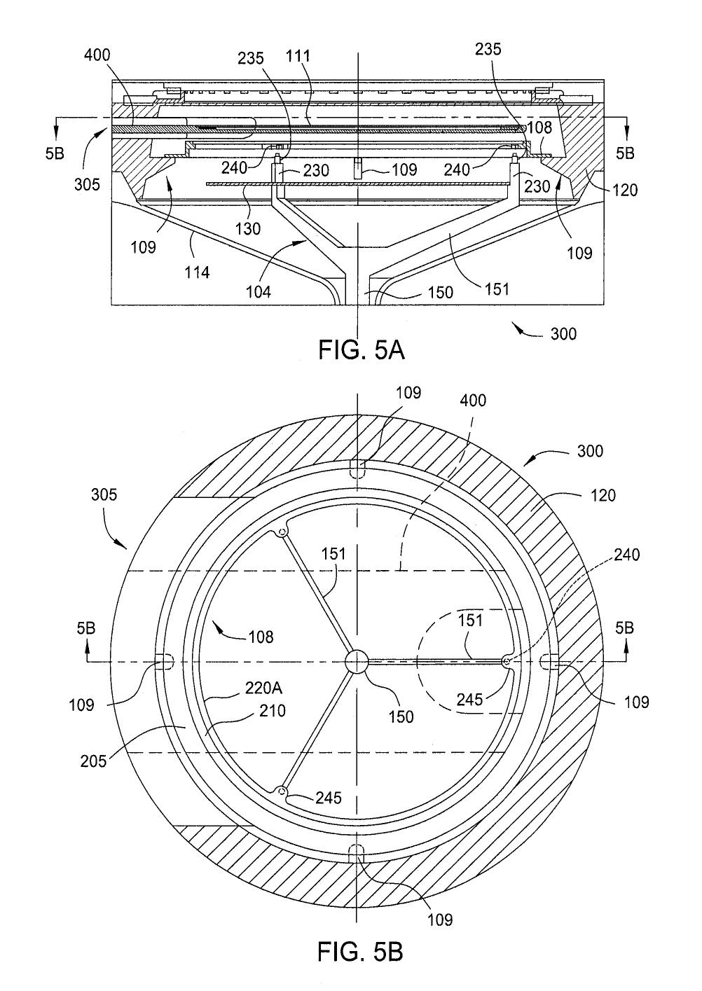

FIG. 5A is a side cross-sectional view of a portion of the processing chamber 300 along line 5A of FIG. 5B. FIG. 5B is a top plan view of the processing chamber 300 along line 5B of FIG. 5A. FIG. 5A shows the support assembly 104 in a lowered position. The substrate carrier 111 is not shown in FIG. 5B in order to more clearly show the position of the support arms 151. The robot blade 400 is also shown in phantom to show the position of the support arms 151. As shown in FIG. 5B, the edge ring 108 is shown supported by the chamber support structures 109. In the lowered position, the lift pins 235 are disengaged from the notch 240 in the inwardly extending tabs 245 of the edge ring 108. In this position, the support shaft 150 may rotate without contact with the edge ring 108.

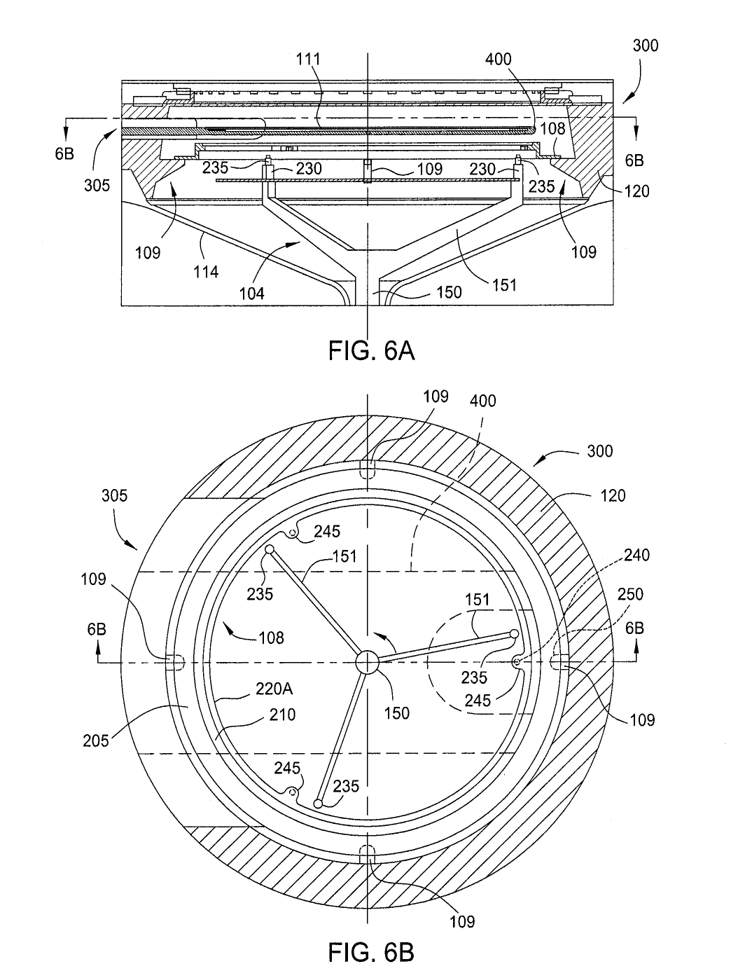

FIG. 6A is a side cross-sectional view of a portion of the processing chamber 300 along line 6A of FIG. 6B. FIG. 6B is a top plan view of the processing chamber 300 along line 6B of FIG. 6A. FIGS. 6A and 6B show the rotation of the support shaft 150. The substrate carrier 111 is not shown in FIG. 6B in order to more clearly show the position of the support arms 151. The robot blade 400 is also shown in phantom to show the position of the support arms 151. In FIGS. 6A and 6B, the support shaft 150 is rotated counterclockwise. The support shaft 150 may be rotated in manner where the lift pins 235 are spaced away from the inwardly extending tabs 245 as shown in FIG. 6B. In FIG. 6B, the lift pins 235 of the support arms 151 are shown in a circular pattern similar to a bolt pattern where the lift pins 235 are imaginary bolts. The circular pattern comprises a diameter that is less than an inside diameter of the edge ring 108 and substantially equal to the diameter of the notches 240 (shown in phantom). Although the pattern of lift pins 235 shown in FIG. 6B may be defined as triangular, the term circular is used based on a radial distance from a geometric center of the support shaft 150 to the center of each lift pin 235 to illustrate the bolt pattern instead of measuring point to point. Thus, circular is intended to cover a triangular configuration as shown in FIG. 6B, and a square configuration in the case where four lift pins 235 (not shown) are used. Circular may also be used in the case where more than four lift pins 235 (not shown) are used.

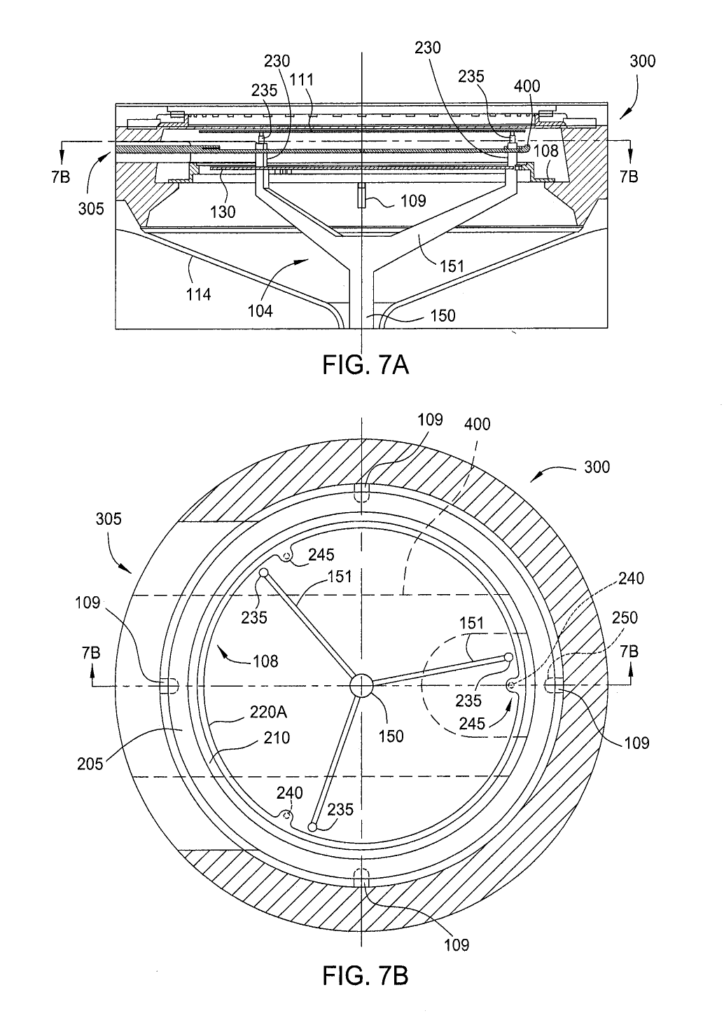

FIG. 7A is a side cross-sectional view of a portion of the processing chamber 300 along line 7A of FIG. 7B. FIG. 7B is a top plan view of the processing chamber 300 along line 7B of FIG. 7A. FIG. 7A shows the support assembly 104 in a raised position to remove the substrate carrier 111 from the robot blade 400. The substrate carrier 111 is not shown in FIG. 7B in order to more clearly show the position of the support arms 151. The robot blade 400 is also shown in phantom to show the position of the support arms 151. The lift pins 235 and a portion of the support members 230 of the support arms 151 protrude through the inside diameter of the edge ring 108 to allow the lift pins 235 to contact the substrate carrier 111.

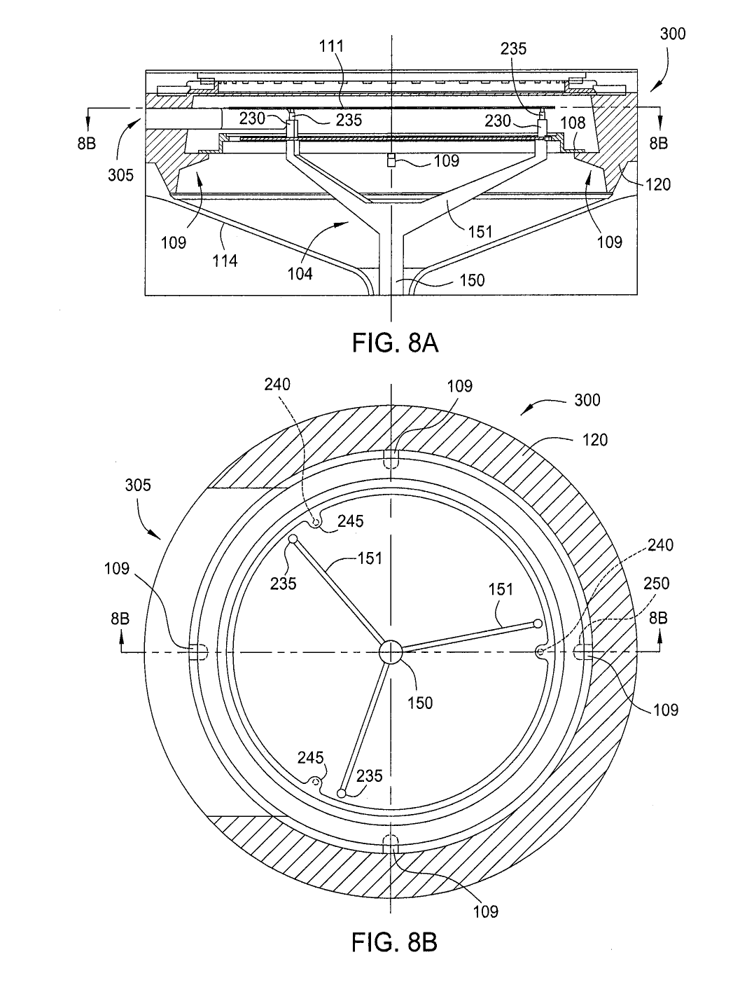

FIG. 8A is a side cross-sectional view of a portion of the processing chamber 300 along line 8A of FIG. 8B. FIG. 8B is a top plan view of the processing chamber 300 along line 8B of FIG. 8A. FIG. 8A shows the robot blade 400 retracted out of the port 305. The substrate carrier 111 is supported by the support assembly 104 as the robot is removed. The substrate carrier 111 is not shown in FIG. 8B in order to more clearly show the position of the support arms 151 and lift pins 235, where the substrate carrier 111 would be supported, as shown in FIG. 8A.

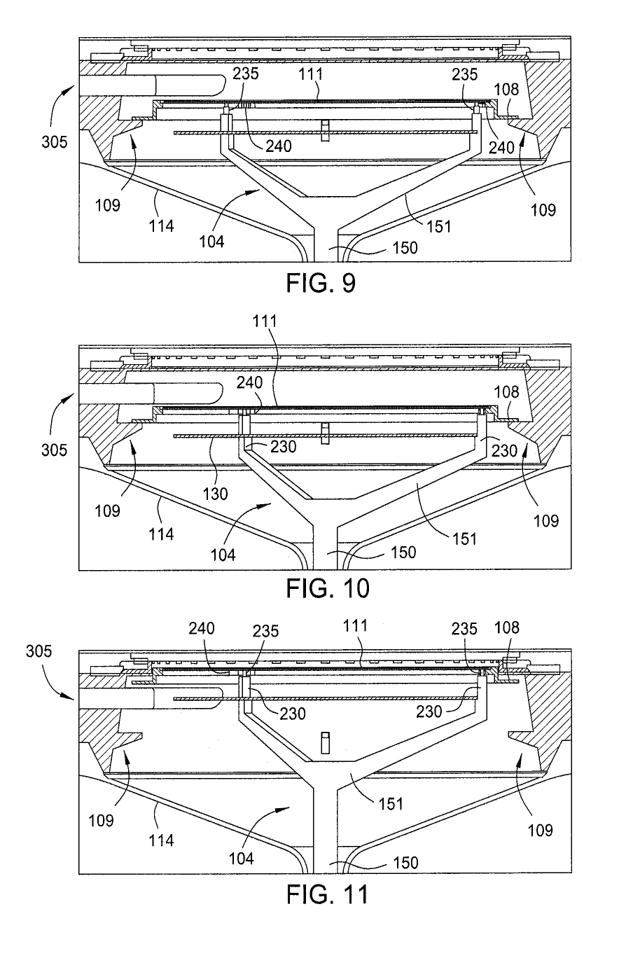

FIG. 9 is a side cross-sectional view of the processing chamber 300 showing the substrate carrier 111 supported by the lift pins 235. The support assembly 104 is moved vertically downward to a position where the periphery of the substrate carrier 111 is received by the edge ring 108. Specifically, the substrate carrier 111 is received in the first upper surface 220A of the edge ring 108. The edge ring 108 is supported by the chamber support structures 109. When the substrate carrier 111 is positioned and supported in the edge ring 108, the support assembly 104 may be lowered vertically to discontinue contact with the substrate carrier 111. The support assembly 104 may be further lowered to allow rotation of the support arms 151 without interference from the substrate carrier 111 or the edge ring 108.

FIG. 10 is a side cross-sectional view of the processing chamber 300 showing the lift pins 235 adjacent in proximity to the inwardly extending tabs 245 of the edge ring 108. The position of the support assembly 104 in FIG. 10 is accomplished by rotating the support shaft 150 from the position shown in FIG. 9 and raising to engage the lift pins 235 with the notches 240 in the inwardly extending tabs 245. The rotation of the support shaft 150 is clockwise in this example. The position of the support assembly 104 in FIG. 10 may be considered the home position as shown in FIGS. 3A and 3B.

FIG. 11 is a side cross-sectional view of the processing chamber 300 showing the support assembly 104 in a raised position. The support assembly 104 is supporting the substrate carrier 111 supported by the lift pins 235. This position may be a processing position where the substrate carrier 111 is moved closer to or away from the showerhead assembly 118 or the energy source 122 (both shown in FIG. 1). The support assembly 104 may be rotated during processing and moved vertically to adjust the space between the substrate carrier 111 and the showerhead assembly 118, thereby controlling temperature of the substrates 140 (not shown).

After processing, the support assembly 104 may be lowered to a position where the edge ring 108 is again supported by the chamber support structures 109. The support assembly 104 may be further lowered to disengage the lift pins 235 from the notches 240 in the inwardly extending tabs 245 of the edge ring 108, as shown in FIG. 5A. The support assembly 104 may then be rotated to be clear of the inwardly extending tabs 245. Once clear of the inwardly extending tabs 245, the support assembly 104 may be raised to allow the lift pins 235 to contact the substrate carrier 111 and lift the substrate carrier 111 to a transfer position. A robot blade, such as the robot blade 400 shown in FIGS. 4A-6B may positioned under the substrate carrier 111. The support assembly 104 may then be lowered to disengage the substrate carrier 111 onto the robot blade. The robot blade having the substrate carrier 111 supported thereon is then retracted out of the processing chamber 300. After removal of the substrate carrier 111 with processed substrates, another substrate carrier 111 having to-be-processed substrates thereon may be transferred to the processing chamber 300. Thus, the transfer and processing procedure described in FIGS. 4A-11 may be repeated.

Embodiments described herein provide a method and apparatus utilizing a single lift and rotational mechanism 105 to facilitate transfer of one or more substrates into a processing chamber and facilitate processing of the one or more substrates in the processing chamber. The single lift and rotational mechanism 105 may be a support assembly 104 as described herein having a plurality of lift pins 235. The single lift and rotational mechanism 105 may also comprise a plurality of lift pins 235 coupled to a common actuator (or set of actuators) that facilitates simultaneous movement of the lift pins 235 and enabling selective support of a substrate carrier 111 as described herein. The single lift and rotational mechanism 105 reduces moving parts within the processing chamber by eliminating the need for dedicated transfer devices and devices utilized for lifting and/or rotation during processing. Elimination of moving parts reduces the possibility of particle contamination and/or collisions that may cause damage to the processing chamber components or substrates therein. Thus, the single lift and rotational mechanism 105 as described herein increases productivity by minimizing downtime of the processing chamber.

While the foregoing is directed to embodiments of the present invention, other and further embodiments of the invention may be devised without departing from the basic scope thereof, and the scope thereof is determined by the claims that follow.

What is claimed is:

1. A method for processing one or more substrates, comprising:
transferring a substrate carrier, having one or more substrates disposed thereon, to a chamber volume;
supporting the substrate carrier within the chamber volume using a set of lift pins;
transferring the substrate carrier from the set of lift pins to an edge ring within the chamber volume; and
contacting the edge ring with the set of lift pins to control the position of the substrate carrier within the chamber volume.

2. The method of claim 1, wherein the set of lift pins are commonly actuated.

3. The method of claim 1, wherein the chamber volume comprises a heat source and a showerhead opposite the heat source.

4. The method of claim 3, further comprising:
controlling the spacing between the substrate carrier and the showerhead by moving the set of lift pins.

5. The method of claim 1, further comprising:
supporting the edge ring on a stationary support surface within the chamber volume when the set of lift pins are supporting the substrate carrier.

6. The method of claim 1, wherein the contacting the edge ring comprises:
rotating the set of lift pins; and
aligning each of the lift pins with a tab disposed on an inside diameter of the edge ring.

7. The method of claim 6, wherein the supporting the substrate carrier comprises:
moving each of the lift pins through the inside diameter of the edge ring.

8. The method of claim 6, wherein the set of lift pins are coupled to a common lift shaft that is vertically and rotationally movable.

9. A method for processing one or more substrates, comprising:
transferring one or more substrates disposed on a substrate carrier supported by a robot blade to a chamber;
moving a plurality of lift pins into contact with the substrate carrier;
supporting the substrate carrier above a plane of the robot blade;
moving the robot blade out of the chamber;
moving the substrate carrier into a supported position on an edge ring;
moving the lift pins to a position where each of the plurality of lift pins are engaged with the edge ring; and
lifting the edge ring and the substrate carrier to a processing position.

10. The method of claim 9, wherein the lift pins are commonly actuated.

11. The method of claim 10, wherein the plurality of lift pins are utilized to lift the edge ring.

12. The method of claim 9, wherein the moving the lift pins comprises:
rotating each of the lift pins to align each lift pin with a tab disposed on an inside diameter of the edge ring.

13. The method of claim 12, wherein the supporting the substrate carrier comprises:
moving at least a portion of each of the lift pins through the inside diameter of the edge ring.

14. The method of claim 12, wherein the lift pins are coupled to a common lift shaft that is vertically and rotationally movable.

15. The method of claim 9, wherein the chamber volume comprises a heat source and a showerhead opposite the heat source.

16. The method of claim 15, further comprising:
controlling the spacing between the substrate carrier and the showerhead.

17. An apparatus for processing multiple substrates, comprising:
a chamber body having an internal sidewall;
a plurality of chamber support features coupled to an interior surface of the internal sidewall and extending into the processing volume;
an edge ring disposed in the processing volume, the edge ring comprising:
an annular body;
a shoulder portion, the shoulder portion defining an inner diameter of the annular body; and
a plurality of tabs disposed on the shoulder portion in a circular pattern having a diameter that is less than the inner diameter of the annular body; and
a support assembly disposed in the processing volume, the support assembly having at least three lift pins that are selectively movable to a first position to engage the plurality of tabs and a second position to extend through the inner diameter of the annular body.

18. The apparatus of claim 17, wherein each of the at least three lift pins are coupled to a single lift shaft, the single lift shaft coupled to an actuator that moves the single lift shaft linearly and rotationally.

19. The apparatus of claim 17, wherein each of the plurality of tabs comprise a notch to facilitate engagement with a lift pin.

20. The apparatus of claim 17, wherein each of the plurality of chamber support features comprise a support surface for supporting the edge ring.
